(19) United States
(12) Patent Application Publication
(10) Pub. No.: US 2006/0154427 A1
(43) Pub. Date: Jul. 13, 2006

(54) Method of thermally treating a wafer and method of fabricating a semiconductor device using the same

(76) Inventor: Jun-Seuck Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/318,585

(22) Filed: Dec. 28, 2005

(30) Foreign Application Priority Data
Jan. 13, 2005 (KR) 2005-0003236

(51) Int. Cl. H01L 21/477

(52) U.S. Cl. 438/301; 438/308; 438/795

(57) ABSTRACT

A method of thermally treating a semiconductor wafer is disclosed. The method comprises loading a wafer into a chamber, adjusting the vacuum pressure in the chamber, increasing the temperature of the wafer, and maintaining the vacuum pressure and temperature for a period of time sufficient to activate conductive impurities that were implanted in the wafer.

### BACKGROUND OF THE INVENTION

1. Field of the Invention

Embodiments of the present invention relate to a method of fabricating a semiconductor device. More particularly, embodiments of the invention relate to a method of thermally treating a semiconductor wafer to form a shallow junction MOS transistor.

This application claims the benefit of Korean Patent Application No. 2005-0003236, filed Jan. 13, 2005, the disclosure of which is hereby incorporated by reference in its entirety.

2. Discussion of Related Art

As the degree of semiconductor device integration has increased, it has been necessary to reduce transistor size within semiconductor devices. However, there is a finite limit to the amount by which a junction depth for the source/drain regions of a transistor may be reduced. For example, consider one problem inherent in the recent move in contemporary designs from a long channel, MOS transistor to a short channel, MOS transistor having a length less than 0.5 μm. For this design, when the depletion region of a source or drain region penetrates into the short channel, the effective channel length is further reduced, thereby reducing the threshold voltage of the transistor. At a certain point, such undesired reductions in the transistor threshold voltage create the so-called, “short channel effect.” Short channel effects ultimately lead to a loss of control over the transistor, as the reduced threshold voltage falls outside the range of gate control voltages applied to the transistor.

Further, as the channel length for MOS transistors is reduced, hot carriers are generated by high electric fields applied across the. Hot carriers cause collision ionization and if they penetrate into oxide layer(s) forming the transistor, the oxide layer(s) will deteriorate.

Several remedies, whole or in part, for the short channel effect have been suggested. For example, the thickness of the gate insulating layer may be reduced, and/or the maximum width of the source and drain regions may be reduced, thereby reducing the potential for depletion region penetration into the channel region. Further, the impurity concentration of a wafer may be generally reduced.

In another conventional remedy to the problem of the short channel effects, conductive impurities are implanted into the source and drain regions of a semiconductor substrate at relatively shallow depths. Thereafter, the semiconductor substrate is thermally treated at a predetermined temperature in order to remove damage to the substrate caused during the implantation of the conductive impurities. The thermal treatment process also stabilizes the implanted conductive impurities within the substrate, thereby forming stable, selectively conductive, shallow junction regions acting as source and drain regions.

Additionally, the thermal treatment process activates the conductive impurities implanted in the substrate. The term “activate” denotes a process whereby the conductive impurities are diffused in a radial manner from the point of implantation within the substrate. This radial diffusion or activation largely determines the final channel length for the MOS transistor. Accordingly, the substrate must be thermally treated under carefully controlled conditions in order to properly activate the conductive impurities within the substrate to accurately form a transistor channel length in a controlled and reproducible manner. Otherwise, production yield for semiconductor devices incorporating such MOS transistors will suffer.

The thermal treatment of semiconductor wafers, where such wafers contain multiple semiconductor substrates supporting multiple respective semiconductor devices comprising many MOS transistors, has been conventionally performed inside a furnace. However, use of conventional furnaces to thermally treat semiconductor wafers suffer from several problems. For example, many conventional furnaces have quartz walls that shed contaminating particles. Air is undesirably introduced into the furnace during the loading and unloading of semiconductor wafers. More significantly, heat provided by the furnace is inefficiently used due to the relatively slow temperature increase provided by conventional furnaces and due to non-uniform heating across the semiconductor wafer(s) being thermally treated. The slow and uneven heating ability of conventional techniques using conventional furnaces adversely effects control over the heat budget designed as part of the thermal treatment process.

In response to these noted deficiencies in conventional thermal treatment techniques, rapid thermal process (RTP) technology has been investigated. Initially, RTP was not widely adopted for use in the thermal treatment of semiconductor wafers because of difficulties associated with maintaining a uniform wafer temperature, maintaining uniform temperature-time characteristics across a batch of wafers during the replacement of a wafer within the batch, and accurately measuring and controlling RTP temperatures. However, with the development of various technologies adapted to the maintenance of uniform wafer temperatures and the measurement and control of RTP temperatures, RTP technology has become more widely accepted.

RTP is typically applied to a single wafer rather than a batch of wafers, and as such it is easier to control the process variables associated with thermal treatment of the wafer. That is, control over the processing environment (e.g., the pressure and temperature of gases inside a RTP chamber), is far superior to that of the conventional furnace, such as those commonly used to perform thermal treatments adapted, for example, to the formation of a titanium nitride layer, metal silicide, glass reflow, a CMOS gate electrode, a DRAM storage electrode, etc. In addition, use of a RTP apparatus is superior to the use of a conventional furnace in the activation of conductive impurities implanted in a semiconductor wafer. Indeed, use of the RTP apparatus in this capacity offers improved productivity over use of the conventional furnace as higher throughput speed may be obtained.

However, the conventional use of an RTP apparatus to perform thermal treatment of a semiconductor wafer is not without its own problems. Most notable among these problems is one in which variations in the temperature of a thermal treatment process being performed using a RTP to activate conductive impurities implanted in a semiconductor wafer may result in changes (i.e., undesirable variation) in the junction depth of MOS transistors formed on the semiconductor wafer. Such junction depth variations due to the temperature variations at the margins of the RTP processing may reduce production yield.

### SUMMARY OF THE INVENTION

Therefore, embodiments of the invention address the problem of potentially diminished production yields caused by variable junction depths resulting from inadequate processing margins associated with thermal treatments obtained by the use of RTP.

In one embodiment, the invention provides a method of thermally treating a semiconductor wafer having first and second conductivity type impurities implanted therein, the method comprising; loading the semiconductor wafer into a chamber; forming a vacuum pressure in the chamber in a range from about 1 mTorr to about 5 mTorr, increasing the temperature of the semiconductor wafer, and maintaining the vacuum pressure and temperature for a period of time sufficient to activate the first and second conductivity type impurities.

In another embodiment, the invention provides a method of fabricating a semiconductor device, comprising; implanting first conductivity type impurities into a surface of a substrate, forming a gate electrode on the substrate, forming a spacer on the gate electrode, implanting second conductivity type impurities into the surface of the wafer using the gate electrode and spacer as a mask to form a source/drain impurity region separated on either side of the gate electrode across a channel region, loading the substrate into a chamber, forming a vacuum pressure in the chamber in a range from about 1 mTorr to about 5 mTorr, increasing the temperature of the substrate, and maintaining the vacuum pressure and temperature for a period of time sufficient to activate the first and second conductivity type impurities.

### BRIEF DESCRIPTION OF THE DRAWINGS

Exemplary embodiments of the invention will now be described with reference to the accompanying drawings, in which like reference symbols refer to like elements and the thicknesses of layers and regions have been exaggerated for clarity. In the drawings:

FIGS. 1A through 1L are cross sectional views illustrating a method of fabricating a semiconductor device in accordance with one embodiment of the invention;

FIG. 2 shows a rectangular wire model that illustrates the electrical characteristics of the semiconductor device thermally treated using a method of fabricating a semiconductor device in accordance with the present invention; and

FIGS. 3 and 4 are graphs illustrating the values of Table 1.

### DESCRIPTION OF EXEMPLARY EMBODIMENTS

When an element or layer is referred to as being “on” or formed “on” another layer or element, it may be on or formed on that other layer or element directly, or intervening layers or elements may be present.

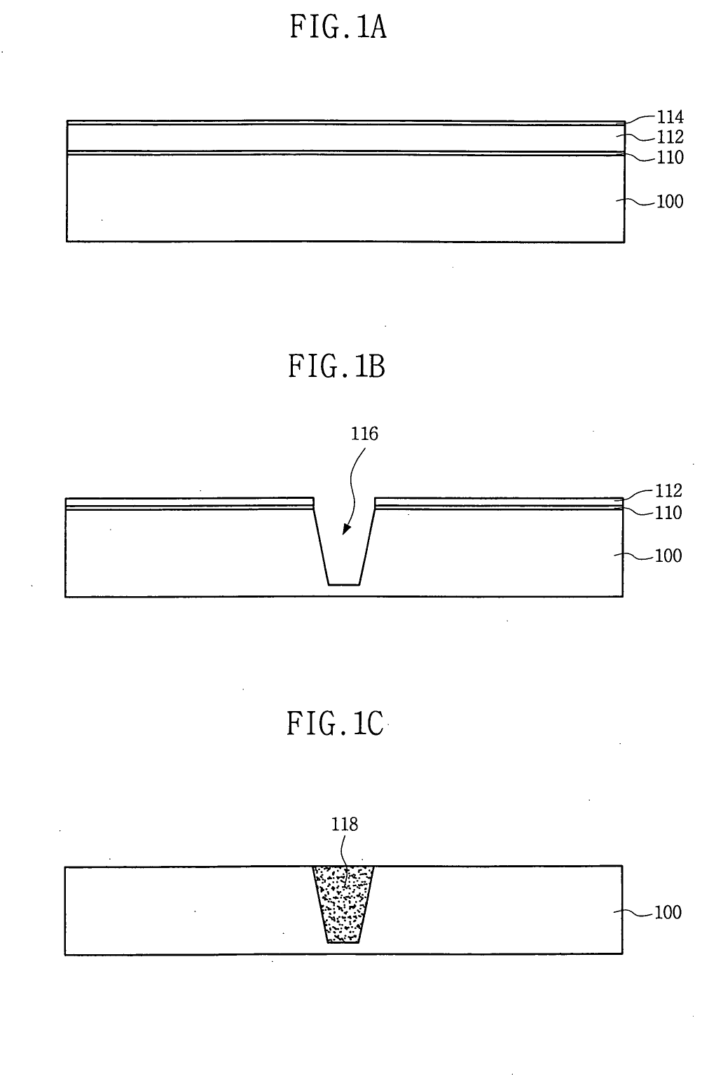

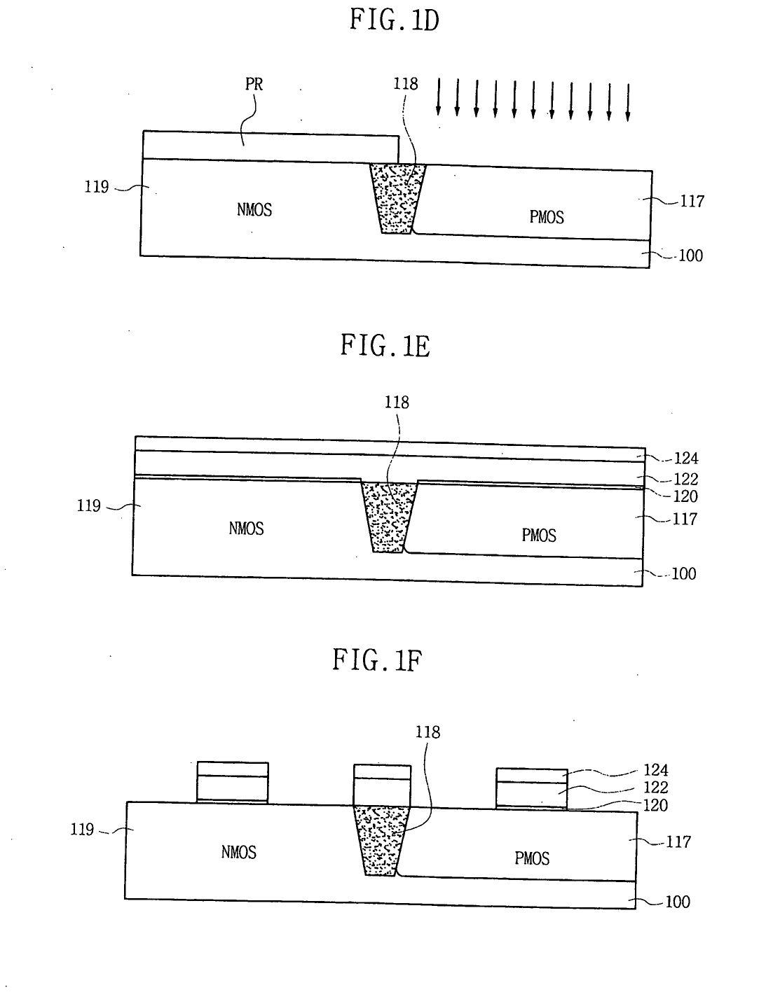

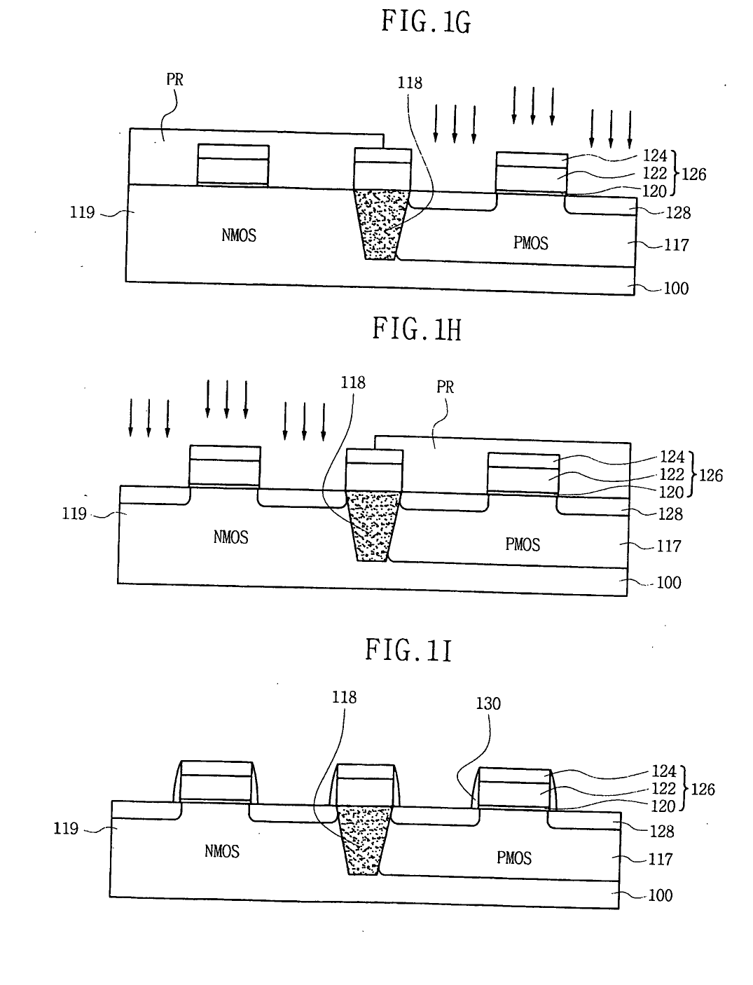

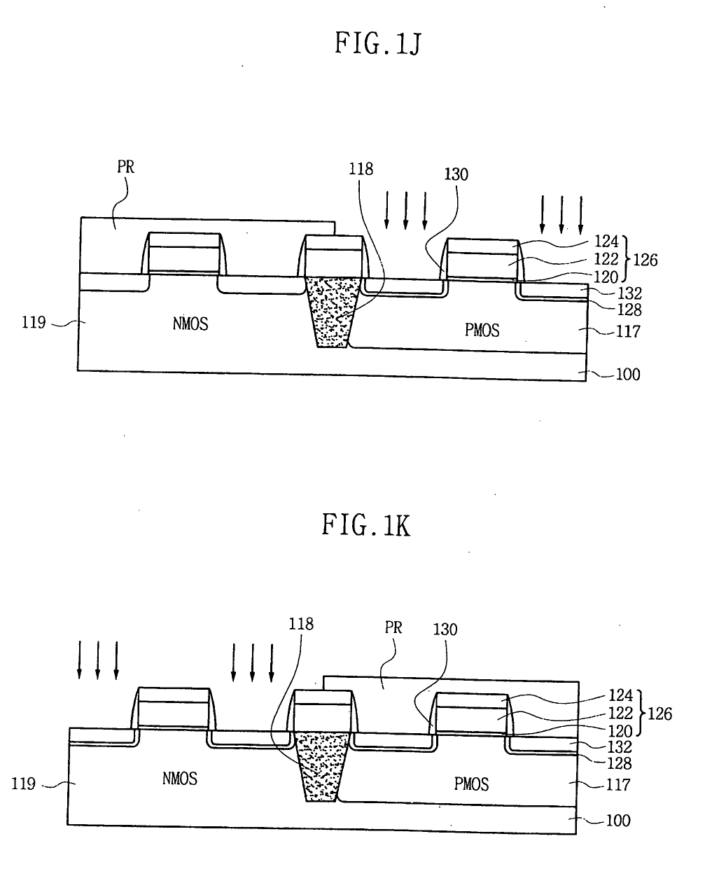

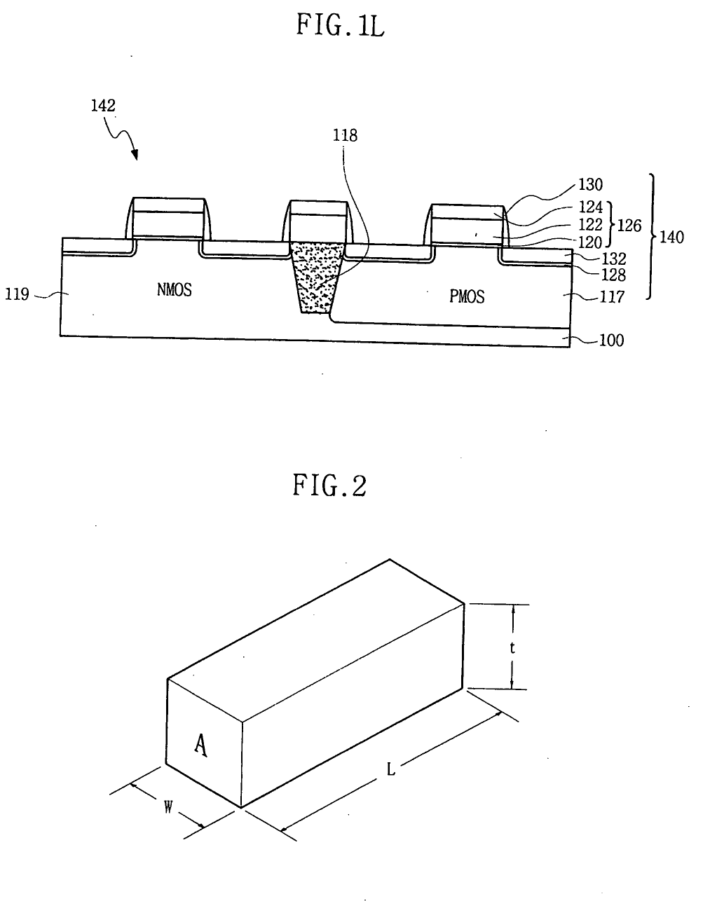

FIGS. 1A through 1L are cross-sectional views illustrating a method of fabricating a semiconductor device in accordance with one embodiment of the invention.

Referring to FIG. 1L, an exemplary method of forming a PMOS transistor 140 and an NMOS transistor 142 will be described with reference to FIGS. 1A through 1L. PMOS transistor 140 comprises PMOS channel impurity region 117, a source/drain impurity region 132, a source/drain lightly doped drain (LDD) region 128, and a gate stack 126 comprising a gate insulating layer 120, a gate electrode 122, and a gate upper insulating layer 124. NMOS transistor 142 comprises NMOS channel impurity region 119, a source/drain impurity region 132, a source/drain LDD region 128, and a gate stack 126 comprising a gate insulating layer 120, a gate electrode 122, and a gate upper insulating layer 124.

Referring to FIGS. 1A and 1L, an etch stop layer 110, a hard mask layer 112, and an antireflection layer 114 are sequentially formed on a semiconductor wafer 100, which is doped with first conductivity type impurities (for example, p-type impurities) in the method of fabricating a semiconductor device in accordance with the present invention. The first conductivity type impurities with which wafer 100 is doped function as channel impurities of NMOS channel impurity region 119 formed in NMOS transistor 142, which is formed on wafer 100.

As an example, the first conductivity type impurities are p-type impurities composed of boron or BF₂, and are doped over the whole surface of wafer 100 at a concentration of about 1×10¹³ atoms/cm² to 1×10¹⁴ atoms/cm². Further, etch stop layer 110 is formed using a rapid thermal treatment process or chemical vapor deposition (CVD) process. Etch stop layer 110 is formed of silicon oxide and is formed to have a thickness of about 100 Å to 500 Å. Hard mask layer 112 is formed using a CVD process, is formed of polysilicon, and is formed to have a thickness of about 300 Å to 2000 Å. Antireflection layer 114 is formed using a CVD process, is formed of silicon nitride, and is formed to have a thickness of about 100 Å to 300 Å. The foregoing description of the formation of etch stop layer 110, hard mask layer 112, and antireflection layer 114 is just one example of how those layers may be formed.

Referring to FIG. 1B, photoresist (not shown) is deposited on wafer 100. The photoresist is then selectively patterned to expose a portion of antireflection layer 114 at an area where an isolation layer will be formed. Then, a portion of antireflection layer 114 and a portion of hard mask layer 112 are removed using a dry etching process that uses the photoresist as an etch stop layer. If, during the dry etching process, etch stop layer 110 is exposed during the etching of hard mask layer 112, the etching of hard mask layer 112 is stopped, and the photoresist pattern is removed.

Then, a portion of etch stop layer 110 is removed and wafer 100 is etched to a predetermined depth through a dry etching process using the remaining portions of antireflection layer 114 or the remaining portions of hard mask layer 112 as an etch mask, thereby forming a trench 116. As an example, trench 116 may be formed to have a depth of about 2000 Å to 8000 Å.

During the formation of trench 116, portions of antireflection layer 114 and hard mask layer 112 or all remaining portions thereof may be removed by a reaction gas used to remove etch stop layer 110 and etch wafer 100.

Referring to FIG. 1C, a field oxide layer such as a silicon oxide layer is formed on wafer 100 such that it fills trench 116. Portions of the field oxide layer, the remaining portions of hard mask layer 112, and the remaining portions of etch stop layer 110 are then removed using a chemical mechanical polishing (CMP) process or an etch-back process, which also exposes the surface of wafer 100, and thereby forms an isolation layer 118 inside trench 116. Isolation layer 118 functions as a stop layer to define and isolate active regions on each side of isolation layer 118. Thus, for example, an NMOS transistor may be formed on one side of isolation layer 118 and a PMOS transistor may be formed on the other side of isolation layer 118. In addition, hard mask layer 112 may function as a buffer layer for alleviating the stress due to the volume expansion that occurs during the formation of the field oxide layer.

Referring to FIG. 1D, photoresist PR is deposited on the surface of wafer 100. Photoresist PR is then patterned to expose an active region located on one side of isolation layer 118.

Then, second conductivity type impurities are implanted into the exposed active region using photoresist PR as an ion implantation mask, thereby forming PMOS channel impurity region 117. The first and second conductivity type impurities have opposite conductivities. The active region that is not exposed (i.e., the active region located on the other side of isolation layer 118 from PMOS channel impurity region 117) is NMOS channel impurity region 119. As an example, the second conductivity type impurities may be n-type impurities comprising phosphorus (P) or arsenic (As), and may be implanted into the exposed active region with an ion implantation energy of about 30 keV or greater at a concentration of about 1×10¹³ atoms/cm² to 1×10¹⁴ atoms/cm².

Referring to FIG. 1E, photoresist PR is removed, and gate insulating layer 120, gate electrode 122, and gate upper insulating layer 124 are sequentially formed on PMOS channel impurity region 117 and NMOS channel impurity region 119.

As one example, gate insulating layer 120 is formed using a rapid thermal treatment process, is formed of silicon oxide, and is formed to have a thickness of about 100 Å or less. Gate electrode 122 and gate upper insulating layer 124 are formed using a CVD process. Gate electrode 122 is formed of polysilicon doped with conductive impurities, and is formed to have a thickness of about 200 Å to 800 Å. Gate upper insulating layer 124 is formed of silicon oxide or silicon nitride, and is formed to have a thickness of about 200 Å to 500 Å. The foregoing description of the formation of gate insulating layer 120, gate electrode 122, and gate upper insulating layer 124 is just one example of how those layers may be formed.

Referring to FIGS. 1F and 1L, photoresist (not shown) is deposited on the surface of wafer 100. The photoresist is then patterned to expose portions of gate upper insulating layer 124. Portions of gate upper insulating layer 124 on NMOS channel impurity region 119 are exposed, portions of gate upper insulating layer 124 on PMOS channel impurity region 117 are exposed, and portions of gate upper insulating layer 124 on other parts of the surface of wafer 100 are also exposed. However, the portion of gate upper insulating layer 124 that is on isolation layer 118 is not exposed. Then, portions of gate upper insulating layer 124, gate electrode 122, and gate insulating layer 120 are removed through a dry etching process using the photoresist as an etch mask. Hereafter, the stack structures formed by the remaining portions of gate insulating layer 120, gate electrode 122, and gate upper insulating layer 124 will be referred to as gate stacks 126. The width of gate stacks 126 is a critical dimension (CD) related to the structure of PMOS transistor 140 and NMOS transistor 142. The CD may, for example, be reduced to 0.5 μm or less in accordance with recent developments in semiconductor fabrication technology. In order to prevent damage to the surface of wafer 100 during a subsequent ion implantation process, (e.g., such as one used to form source/drain LDD region 128), the above dry etching process may be used to remove gate insulating layer 120.

Referring to FIGS. 1G and 1L, photoresist PR is deposited on wafer 100. Photoresist PR is then patterned so that the portion of photoresist PR on PMOS channel impurity region 117 is removed. Source/drain LDD region 128 for PMOS transistor 140 is formed by implanting first conductivity type impurities into PMOS channel impurity region 117 using an ion implantation process and using photoresist PR and gate stack 126 of PMOS transistor 140 as ion implantation masks. Photoresist PR is then removed. Source/drain LDD region 128 of PMOS transistor 140, which is doped with first conductivity type impurities, form shallow junctions within PMOS channel region 117, which is doped with second conductivity type impurities.

As an example, the first conductivity type impurities that are implanted into source/drain LDD region 128 of PMOS transistor 140 may comprise boron or BF₂, and may be implanted with an ion implantation energy of about 5 keV to 20 keV at a concentration of about 1×10¹³ atoms/cm² to 1×10¹⁴ atoms/cm².

Referring to FIGS. 1H and 1L, photoresist PR is deposited on the surface of wafer 100. Photoresist PR is then patterned to expose NMOS channel impurity region 119.

Source/drain LDD region 128 of NMOS transistor 142 is formed by implanting second conductivity type impurities into NMOS channel impurity region 119 using an ion implantation process and using photoresist PR and gate stack 126 of NMOS transistor 142 as ion implantation masks. Photoresist PR is then removed. Source/drain LDD region 128 of NMOS transistor 119, which is doped with second conductivity type impurities, forms a shallow junction with NMOS channel region 119, which is doped with the first conductive impurities.

As an example, the second conductivity type impurities that are implanted into source/drain LDD region 128 of NMOS transistor 142 may comprise phosphorus or arsenic, and may be implanted with an ion implantation energy of about 10 keV to 20 keV at a concentration of about 1×10¹³ atoms/cm² to 1×10¹⁴ atoms/cm².

Referring to FIG. 1I and 1L, an interlayer insulating layer such as a silicon oxide layer or a silicon nitride layer is formed on wafer 100. Spacers 130 are then formed on the sidewalls of gate stacks 126 of PMOS transistor 140 and NMOS transistor 142 by isotropically etching the interlayer insulating layer to expose portions of source/drain LDD region 128.

Spacer 130 functions to insulate gate electrode 122 from a source/drain electrode that will be formed subsequently. If, as described above, gate insulating layer 120 was not removed when portions of upper insulating layer 124 and gate electrode 122 were removed, gate insulating layer 120 may be removed during the formation of spacer 130.

Referring to FIGS. 1J and 1L, photoresist PR is deposited on the surface of wafer 100. Photoresist PR is then patterned to expose PMOS channel impurity region 117. Source/drain impurity region 132 of PMOS transistor 140 is then formed by implanting first conductivity type impurities into source/drain LDD region 128 of PMOS transistor 140 using photoresist PR, gate stack 126 of PMOS transistor 140, and spacers 130 of PMOS transistor 140 as ion implantation masks. Photoresist pattern PR is then removed.

Source/drain impurity region 132 of PMOS transistor 140 is doped with a high concentration of first conductivity type impurities in order to reduce contact resistance of a source/drain electrode subsequently connected to the region, and to improve electrical conductivity of the region.

As an example, the first conductivity type impurities that are implanted into source/drain impurity region 132 of PMOS transistor 140 may comprise boron or BF₂, and may be implanted with an ion implantation energy of about 5 keV to 10 keV at a concentration of about 1×10¹⁴ atoms/cm² to 1×10¹⁵ atoms/cm².

Referring to FIGS. 1K and 1L, photoresist PR is deposited on the surface of wafer 100. Photoresist PR is then patterned to expose NMOS channel impurity region 119. Source/drain impurity region 132 of NMOS transistor 142 is then formed by implanting second conductivity type impurities into source/drain LDD region 128 of NMOS transistor 142 using photoresist PR formed on PMOS transistor 140, gate stack 126 of NMOS transistor 142, and spacers 130 of NMOS transistor 142 as ion implantation masks. Photoresist PR is then removed.

Source/drain impurity region 132 of NMOS transistor 142 is doped with a high concentration of second conductivity type impurities in order to reduce contact resistance of a subsequently formed source/drain electrode, and to improve an electrical conductivity of the region.

As an example, the second conductivity type impurities that are implanted into source/drain impurity regions 132 of NMOS transistor 142 may comprise boron or arsenic, and may be implanted with an ion implantation energy of about 1 keV to 10 keV at a concentration of about 1×10¹⁴ atoms/cm² to 1×10¹⁵ atoms/cm². Also, source/drain impurity regions 132 of NMOS transistor 142 may be formed at the surface of wafer 100, and, for example, may be formed at the surface of wafer 100 to a depth of about 1000 Å from the surface of wafer 100.

Referring to FIG. 1L, the first conductivity type impurities that are implanted in source/drain LDD region 128 and source/drain impurity region 132 of PMOS transistor 140 are activated using a rapid thermal process (RTP). The second conductivity type impurities that are implanted in source/drain LDD region 128 and source/drain impurity region 132 of NMOS transistor 142 are also activated using the RTP.

As used herein, the term “activate” not only denotes a process whereby the conductive impurities are diffused in a radial manner from the point of implantation within the substrate, but also denotes a process by which the sheet resistance of the substrate is adjusted through the diffusion of said impurities.

The RTP for activating the first conductivity type impurities and the second conductivity type impurities in the source/drain LDD regions 128 and the source/drain impurity regions 132 is performed in a RTP apparatus that is capable of rapidly increasing the temperature of a wafer from the room temperature to a predetermined temperature, or gradually increasing the temperature of a wafer to a predetermined temperature through multiple intermediate temperatures, at least one of which is a relaxation temperature. In addition to the temperature, the vacuum pressure inside the apparatus is also controlled as a variable in the RTP in order to reduce the diffusion speed of the implanted impurities during the process of activating the implanted first conductivity type impurities and/or the implanted second conductivity type impurities.

As an example, during the RTP, wafer 100 may be rapidly thermally treated at a temperature of about 1010° C. to 1020° C. in a high vacuum state of about 1 mTorr (1×10⁻³ Torr) or less for about 2 to 5 seconds. An exemplary RTP will now be described in some additional detail.

First, wafer 100, in which the first conductivity type impurities and the second conductivity type impurities are implanted, is loaded into a chamber (not shown) of the RTP apparatus, wherein the chamber comprises a sealed room. Next, the air inside the chamber is pumped out. As an example, the air inside the chamber may be pumped out using a low vacuum pump such as a dry pump and a high vacuum pump such as a turbo pump, a diffusion pump, a cryo pump, and/or an ion pump. Using any one or more of such conventional pumps, the chamber is pumped to a vacuum pressure of about 1×10⁻⁶ Torr or less by the pumping of the low vacuum pump and the high vacuum pump. Further, by flowing a carrier gas into the chamber while pumping the air inside the chamber, the chamber is brought to a high vacuum pressure of about 1×10⁻³ Torr or less.

Then, if the vacuum pressure inside the chamber is maintained at a stable level, the temperature of wafer 100 is increased to a predetermined temperature by the heat provided by a tungsten halogen lamp, which is a common light source for a RTP apparatus. Wafer 100 is then rapidly thermally treated for a predetermined amount of time.

The electrical characteristics of the semiconductor device fabricated by the thermal treatment of wafer 100 in accordance with the present invention can be analyzed using the formula R=pL/A=(p/t)(L/W).

FIG. 2 shows a rectangular wire model that illustrates the electrical characteristics of the semiconductor device thermally treated using a method of fabricating a semiconductor device in accordance with the present invention. In the foregoing formula, ‘p’ indicates the resistivity of a medium, ‘L’ indicates the length of a rectangular wire to which electricity is applied, ‘A’ indicates the surface area of the cross section of the wire, ‘t’ indicates the thickness of the rectangular wire, and ‘W’ indicates the width of the rectangular-shaped wire.

The sheet resistance (“Rs”) of the model wire may be obtained by normalizing the ratio of the length of the rectangular wire to the width of the rectangular wire (i.e., by setting the ratio L/W equal to 1 in the formula). Thus, the formula shows that sheet resistance Rs is inversely proportional to the thickness of the rectangular wire. The formula also shows that the sheet resistance Rs of a semiconductor device is inversely proportional to the diffusion depth of the implanted conductive impurities, (i.e., the junction depth for the semiconductor device).

Table 1 shows the sheet resistance Rs of an exemplary semiconductor device, wherein a thermal treatment in accordance with one embodiment of the invention was performed on wafer 100 in the process of fabricating the semiconductor device. Table 1 shows the resulting sheet resistance Rs of semiconductor devices fabricated using various combinations of pressures and temperatures in the RTP performed on wafer 100.

TABLE 1

| | Temperature (in ° C.) | | | | | |
|---|---|---|---|---|---|---|
| | 1010 | | | 1012 | | |
| Vacuum | .005 | 5 | 770 | .005 | 5 | 770 |
| Pressure | | | | | | |
| (in Torr) | | | | | | |
| Sheet | 115.40 | 105.50 | 96.04 | 131.90 | 104.10 | 93.81 |
| Resistance | | | | | | |
| (Rs) (in Ω) | | | | | | |

Boron was used as the conductive impurity implanted into wafer 100 during the fabrication of the exemplary semiconductor devices shown in Table 1. The boron was implanted with an energy of about 3 keV to a concentration of about 3×10¹⁵ atoms/cm².

Trials of the RTP were performed at temperatures of 1010° C. and 1012° C. Also, trials of the RTP were performed with a high vacuum pressure of 5 mTorr, a low vacuum pressure of 5 Torr, and a high pressure of 770 Torr, respectively. Table 1 further illustrates that sheet resistance Rs is inversely proportional to the pressure at which the RTP process was performed.

Thus, during the thermal treatment of wafer 100, when the pressure inside the chamber during the thermal process is reduced in accordance with embodiments of the invention, the conductive impurities implanted into wafer 100 were less diffused. Experimental results obtained using an exemplary embodiment of the invention show that as the amount of diffusion of the conductive impurities implanted into wafer 100 increases, the concentration of the conductive impurities implanted into wafer 100 decreases. Likewise, as the amount of diffusion of the conductive impurities implanted into wafer 100 decreases, the concentration of the conductive impurities implanted into wafer 100 increases. However, increases and decreases in the concentration of conductive impurities has little influence on the electrical conductivity of a semiconductor device.

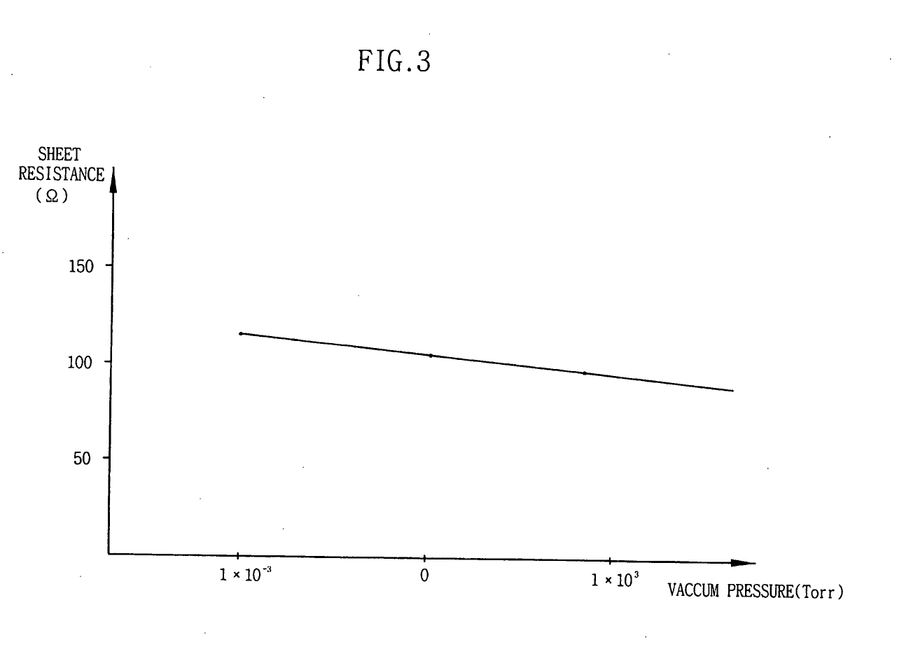

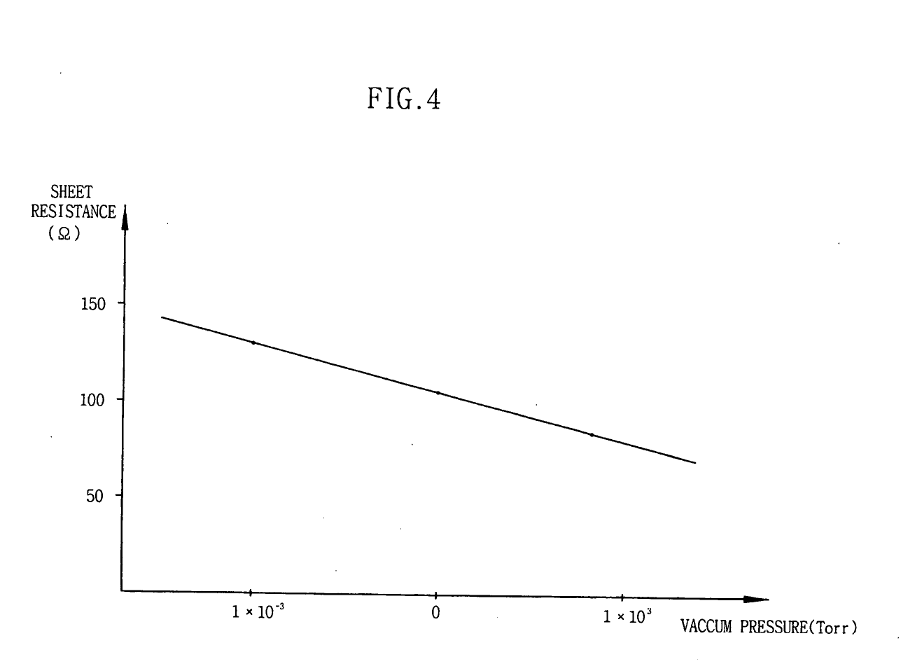

FIGS. 3 and 4 are graphs illustrating the values of Table 1.

Referring to FIGS. 3 and 4, the diffusion of the conductive impurities of wafer 100 during the thermal treatment of wafer 100, in accordance with the present invention, can be decreased by reducing the pressure inside the chamber where the RTP is performed.

The slope of the graph in FIG. 4 is steeper than that of the graph in FIG. 3, indicating that the RTPs of FIG. 4 were performed at a higher temperature than the RTPs of FIG. 3. The RTPs of FIG. 3 were performed at a temperature of about 1010° C., and the RTPs of FIG. 4 were performed at a temperature of about 1012° C.

Therefore, in accordance with embodiments of the invention, wafer 100, in which conductive impurities have been implanted, can be thermally treated rapidly at a vacuum pressure of several mTorr or less to activate the conductive impurities, and a production yield can be increased or maximized because the processing margins associated with the RTP may be increased without much change in the resulting junction depth formed by the thermal treatment.

In accordance with embodiments of the invention, the process of implanting the first conductivity type impurities into PMOS transistor 140 may be performed before the process of implanting the second conductivity type impurities into NMOS transistor 142, or vice versa.

The invention has been described using exemplary embodiments. However, it is to be understood that the scope of the invention is not limited to only the disclosed embodiments. Rather, the scope of the invention is intended to encompass various modifications and alternative arrangements within the capabilities of a person skilled in the art. The scope of the claims, therefore, should be accorded the broadest interpretation so as to encompass all such modifications and similar arrangements.

What is claimed is:

1. A method of thermally treating a semiconductor wafer having first and second conductivity type impurities implanted therein, the method comprising:
loading the semiconductor wafer into a chamber;
forming a vacuum pressure in the chamber in a range from about 1 mTorr to about 5 mTorr;
increasing the temperature of the semiconductor wafer; and,
maintaining the vacuum pressure and temperature for a period of time sufficient to activate the first and second conductivity type impurities.

2. The method of claim 1, wherein the temperature is about 1010° C.

3. The method of claim 2, wherein the period of time ranges from about 2 to about 5 seconds.

4. The method of claim 1, wherein forming the vacuum pressure in the chamber in the range from about 1 mTorr to about 5 mTorr further comprises:
reducing the vacuum pressure in the chamber to about 1×10⁻⁶ Torr or less; and thereafter,
flowing a carrier gas into the chamber to form the vacuum pressure in the chamber in the range from about 1 mTorr to about 5 mTorr.

5. A method of fabricating a semiconductor device, comprising:
implanting first conductivity type impurities into a surface of a substrate;
forming a gate electrode on the substrate;
forming a spacer on the gate electrode;
implanting second conductivity type impurities into the surface of the wafer using the gate electrode and spacer as a mask to form a source/drain impurity region separated on either side of the gate electrode across a channel region;
loading the substrate into a chamber;
forming a vacuum pressure in the chamber in a range from about 1 mTorr to about 5 mTorr;
increasing the temperature of the substrate; and,
maintaining the vacuum pressure and temperature for a period of time sufficient to activate the first and second conductivity type impurities.

6. The method of claim 5, wherein the temperature is about 1010° C. or 1012° C.

7. The method of claim 6, wherein the period of time ranges from about 2 to about 5 seconds.

8. The method of claim 5, wherein forming the vacuum pressure in the chamber in the range from about 1 mTorr to about 5 mTorr further comprises:
reducing the vacuum pressure in the chamber to about 1×10⁻⁶ Torr or less; and thereafter,
flowing a carrier gas into the chamber to form the vacuum pressure in the chamber in the range from about 1 mTorr to about 5 mTorr.

9. The method of claim 5, further comprising:
before forming the spacer, implanting second conductivity type impurities into the substrate on both sides of the gate electrode using the gate electrode as a mask.

10. The method of claim 9, wherein, the second conductive impurities are implanted into the substrate wafer on both sides of the gate electrode using the gate electrode as a mask using an ion implantation energy of between 10 keV to 20 keV to a concentration of between about 1×10¹³ atoms/cm² to 1×10¹⁴ atoms/cm².

11. The method of claim 5, wherein the first conductive impurities comprise phosphorus or arsenic.

12. The method of claim 5, wherein the second conductive impurities comprise boron or BF₂.
